(19) United States
(12) Patent Application Publication
(10) Pub. No.: US 2026/0323826 A1
(43) Pub. Date: Oct. 15, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Dae Sung MOON, Seoul (KR); Dae Gyu AN, Seoul (KR)

(21) Appl. No.: 19/483,702

(22) PCT Filed: May 13, 2024
(86) PCT No.: PCT/KR2024/006504

§ 371 Date: Nov. 12, 2025

(30) Foreign Application Priority Data
May 12, 2023 (KR) 1020230061850

(51) Int. Cl. H05K 1/11; H05K 1/181

(52) U.S. Cl. CPC H05K 1/113; H05K 1/181; H05K 2201/032; H05K 2201/094; H05K 2201/09409; H05K 2201/10522; H05K 2201/10545; H05K 2201/10734

(57) ABSTRACT

A circuit board according to an embodiment includes an insulating layer; an electrode part disposed on the insulating layer; and a surface treatment part disposed on the electrode part, wherein the electrode part includes: a first pad disposed on the insulating layer; and a second pad disposed on the insulating layer and spaced apart from the first pad in a horizontal direction, wherein the surface treatment part includes: a first surface layer provided to cover a portion of an upper surface of the first pad; and a second surface layer provided to surround upper and side surfaces of the second pad.

### TECHNICAL FIELD

An embodiment relates to a circuit board and a semiconductor package including the same.

### BACKGROUND ART

The miniaturization, weight reduction, and integration of electronic components are accelerating, and accordingly, a line width of a circuit is becoming finer. In particular, as semiconductor chip design rules are integrating at a nanometer scale, the line width of the circuit of package substrates or printed circuit boards (PCBs) on which the semiconductor chips are mounted are being refined to a few micrometers or less.

Various processes have been proposed to increase a circuit density of PCBs, i.e., to minimize the line width of the circuit. A semi-additive process (SAP) method and a modified semi-additive process (MSAP) have been proposed for a purpose of preventing a loss of the line width of the circuit in an etching step to form a pattern after copper plating.

Subsequently, in order to realize a finer circuit pattern, an embedded trace substrate (hereinafter referred to as ‘ETS’) method in which copper foil is embedded in an insulating layer is used in a prior art. The ETS method manufactures a copper circuit in an embedded form in an insulating layer rather than forming the copper circuit on a surface of the insulating layer, and as a result, there is no circuit loss due to etching, so it is advantageous to refine a circuit pitch.

Meanwhile, these circuit boards include bump parts for mounting semiconductor devices or connecting to external substrates.

Conventional circuit boards form the bump parts by electroplating on a pad part located at an uppermost side. To achieve this, a seed layer for electroplating the bump part is provided between the pad part and the bump part.

However, conventional circuit boards can suffer from damage to the protective layer and contamination of the surface of the circuit board during a process of forming the seed layer for electroplating the bump part and/or removing the seed layer.

In addition, conventional circuit boards have limitations in securing adhesion between the bump part and the pad part as the bump part protrudes on the pad part with the seed layer in between, and in some cases, there is a reliability problem in which the bump part is peeled off from the Pad part.

### DISCLOSURE

### Technical Problem

An embodiment provides a circuit board having a novel structure and a semiconductor package including the same.

In addition, the embodiment provides a circuit board having a plurality of bump parts having uniform heights and a semiconductor package including the same.

In addition, the embodiment provides a circuit board having improved adhesion between a pad part and a bump part and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; an electrode part disposed on the insulating layer; and a surface treatment part disposed on the electrode part, wherein the electrode part includes: a first pad disposed on the insulating layer; and a second pad disposed on the insulating layer and spaced apart from the first pad in a horizontal direction, wherein the surface treatment part includes: a first surface layer provided to cover a portion of an upper surface of the first pad; and a second surface layer provided to surround upper and side surfaces of the second pad.

In addition, the electrode part further includes: a third pad disposed on the insulating layer and spaced apart from the first and second pads in the horizontal direction; and a bump part disposed on the third pad, wherein the surface treatment part further includes a third surface layer provided to surround a side surface of the bump part.

In addition, the first and second surface layers includes a same material.

In addition, the third surface layer includes a material different from materials of the first and second surface layers.

In addition, the first and second surface layers are an Electroless Nickel Immersion Gold (ENIG) layer or an Electroless Nickel Electroless Palladium Immersion Gold (ENEPIG) layer, and the third surface layer is an Organic Solderability Preservative (OSP) layer.

In addition, the third surface layer does not contact the third pad.

In addition, the third pad is provided in multiple numbers along a circumferential direction of an upper surface of the insulating layer, and is provided in an outer region of the upper surface of the insulating layer adjacent to a side surface of the insulating layer, and the first pad and the second pad are provided in an inner region of the upper surface of the insulating layer excluding the outer region.

In addition, the circuit board further comprises a protective layer disposed on the insulating layer, wherein the protective layer includes a first through hole overlapping the first pad in a vertical direction, a second through hole overlapping the second pad in the vertical direction, and a third through hole overlapping the third pad in the vertical direction, and a width of at least one of the first to third through holes in the horizontal direction is different from a width of at least one other through hole in the horizontal direction.

In addition, a width of the first through hole in the horizontal direction is smaller than a width of the first pad in the horizontal direction, and a width of the second through hole in the horizontal direction is greater than a width of the second pad in the horizontal direction.

In addition, a width of the third through hole in the horizontal direction is smaller than a width of the third pad in the horizontal direction.

In addition, a width of the bump part in the horizontal direction is smaller than a width of the third through hole in the horizontal direction, and an inner wall of the third through hole does not contact the bump part.

In addition, the semiconductor package further comprises a conductive bonding part disposed between the third pad and the bump part.

In addition, the conductive bonding part includes a same material as the first and second surface layers.

In addition, the conductive bonding part is disposed flatly on the third pad, and the bump part does not overlap the conductive bonding part in the horizontal direction.

In addition, the conductive bonding part includes solder, and the conductive bonding part includes a flat portion disposed between the third pad and the bump part; and an extension portion extending from the flat portion and disposed between an inner wall of the third through hole and a side surface of the bump part.

In addition, an upper surface of the extension portion includes a convex surface, and at least a portion of the third surface layer is disposed to overlap the extension portion in the horizontal direction and cover the convex surface of the extension portion.

Meanwhile, a semiconductor package according to an embodiment includes the circuit board described above and further includes a semiconductor device disposed on the first pad and the second pad.

In addition, the semiconductor package further comprises a main board disposed on the bump part.

In addition, the semiconductor package further comprises a molding member molding the semiconductor device and the bump part, wherein the molding member contacts the third surface layer and does not contact the bump part.

Meanwhile, a semiconductor package according to an embodiment includes an insulating layer; an electrode part disposed on the insulating layer; and a surface treatment part disposed on the electrode part, wherein the electrode part includes first to third pads disposed on the insulating layer and spaced apart from each other in a horizontal direction; and a bump part disposed on the third pad; and the surface treatment part includes a first surface layer provided to cover a portion of an upper surface of the first pad; a second surface layer provided to surround an upper surface and a side surface of the second pad; and a third surface layer provided to surround the side surface of the bump part; wherein the third pad is provided in plurality along a circumferential direction of the upper surface of the insulating layer in an outer region of the upper surface of the insulating layer adjacent to the side surface of the insulating layer, and the first pad and the second pad are provided in an inner region of the upper surface of the insulating layer excluding the outer region.

### Advantageous Effects

A circuit board and a semiconductor package including the same of the embodiment include an insulating layer, an electrode part disposed on the insulating layer, and a surface treatment part disposed on a surface of the electrode part. In addition, the electrode part includes a plurality of pads. The plurality of pads include first and second pads coupled to a semiconductor device. In addition, the plurality of pads include a third pad spaced apart from the first and second pads in a horizontal direction and coupled to a main board. In addition, the electrode part includes a bump part disposed on the third pad. At this time, the surface treatment part includes a first surface layer disposed on the first pad, a second surface layer disposed on the second pad, and a third surface layer disposed on the bump part. The first and second surface layers are an Electroless Nickel Immersion Gold (ENIG) layer or an Electroless Nickel Electroless Palladium Immersion Gold (ENEPIG) layer, and the third surface layer is an Organic Solderability Preservative (OSP) layer.

At this time, the third surface layer contacts a molding member that molds the semiconductor device. The third surface layer is provided on a side surface of the bump part and may not be in contact with a conductive adhesive such as solder. Therefore, the embodiment allows a third surface layer provided in a relatively low-cost OSP method to be disposed on a surface of the bump part. Accordingly, the embodiment may lower a product unit price of the semiconductor package. In addition, the embodiment allows a third surface layer to be provided on a side surface of the bump part to protect the bump part from contaminants such as external moisture or particles that may be exposed during a process of manufacturing the semiconductor package, and can solve reliability problems such as corrosion of a surface of the bump part.

In addition, the embodiment allows the third surface layer to be disposed on the surface of the bump part, thereby improving adhesion with the molding member. For example, the molding member has a relatively higher adhesion with the organic third surface layer than with the bump part, thereby stably protecting the bump part and the semiconductor device through the molding member.

In addition, the first and second surface layers can improve processability in a process of mounting the semiconductor device, allowing the semiconductor device to be stably implemented on the circuit board, thereby allowing the semiconductor device to operate stably.

In addition, the insulating layer includes an overlapping region overlapping the semiconductor device in the vertical direction, the first and second pads are disposed on the overlapping region, and a plurality of third pads are provided surrounding the outside of the overlapping region. For example, the plurality of third pads are provided along a circumferential direction of the overlapping region, thereby ensuring rigidity in an outer region of the circuit board. For example, the bump part can further function to prevent the semiconductor package from being significantly warped in a specific direction, in addition to its function as a post for attaching the main board to the circuit board. In addition, the embodiment allows the circuit board and the main board to be coupled to each other via the bump part, thereby further improving heat dissipation characteristics of the semiconductor package.

In addition, the bump part can be attached or bonded to the third pad. Here, “attached” or “bonded” may have a different meaning than “formed” through a plating process.

For example, when forming a bump part by electroplating on a third pad, a plating seed layer for the bump part is provided between the bump part and the third pad. Accordingly, a comparative example requires a process for forming a plating seed layer for plating the bump part and a process for removing the plating seed layer by etching, which complicates a product process and may reduce product yield.

In contrast, the embodiment forms the bump part on a separate support substrate and attaches or bonds the bump part formed on the support substrate to the third pad of the circuit board. Accordingly, the embodiment can improve the physical and/or electrical reliability of the bump part, thereby enhancing the product reliability of the semiconductor package.

For example, the embodiment does not form the bump part by electroplating on the third pad, but instead attaches or bonds the bump part formed on a separate support substrate to the third pad. To this end, a conductive bonding part is disposed between the third pad and the bump part. The conductive bonding part can be distinguished from a chemical copper plating layer and can provide bonding strength that enables the bump part to be stably attached or bonded to the third pad.

Accordingly, the embodiment may remove the chemical copper plating layer that should be provided between the third pad and the bump part, and accordingly, the adhesion between the third pad and the bump part may be improved. For example, the chemical copper plating layer may have a porous structure, and thus, the adhesive strength with the protective layer may be lower than that of the conductive bonding part of the embodiment.

In contrast, the conductive bonding part of the embodiment may have excellent strength, high durability, and relatively high adhesion to the protective layer compared to the chemical copper plating layer.

Therefore, the embodiment can improve the adhesion between the conductive bonding part and the third pad, thereby improving physical reliability by solving the conductive bonding part peeling from the third pad. In addition, the embodiment can minimize transmission loss of signals transmitted through the third pad and the bump part by improving the adhesion between the third pad and the bump part, thereby improving communication characteristics.

In addition, the embodiment can form the bump part on a separate support substrate, thereby ensuring that a plurality of bumps have a same height, thereby allowing the main board to stably attach to the bump part.

For example, when electroplating is performed on a third pad to form a plurality of bump parts, the plurality of bumps may have different heights due to plating deviation, so it may be necessary to proceed with a polishing process that equalizes the heights of the plurality of bumps. In this case, the polishing process may be performed while the bump part is disposed on the third pad, and accordingly, the circuit board may be damaged during the polishing process. For example, in the polishing process, an impact may be applied to the semiconductor device mounted on the circuit board, and accordingly, the semiconductor device may not operate stably.

In contrast, in the embodiment, after forming a bump part on a separate support substrate, a polishing process may be performed to equalize the heights of a plurality of bumps. Therefore, the embodiment can prevent damage to the semiconductor package during the polishing process, thereby improving product yield. In addition, the embodiment may perform a first polishing process of the bump part on the support substrate, and then perform a second polishing process while the bump part is disposed on the third pad. At this time, a polishing amount in the second polishing process is smaller than a polishing amount in the polishing process performed in the comparative example, and thus damage to the circuit board that may be caused by the polishing process can be minimized.

In addition, when forming a bump part by electroplating on the third pad, a process of plating the bump part must be performed after the protective layer is formed, and damage or contamination of the protective layer may occur during the process of plating the bump part. In addition, when forming a bump part by electroplating on the third pad, it may be difficult to form the bump part within a width smaller than a width of a through hole provided in the protective layer. For example, when forming a bump part by electroplating on the third pad, a width of the bump part in a region overlapping the protective layer in a horizontal direction may be the same as a width of the through hole of the protective layer. Therefore, when forming a bump part by performing electroplating on the third pad, the bump part comes into contact with the protective layer, and the stress acting on the protective layer is directly transferred to the bump part, which may cause physical reliability and/or electrical reliability problems.

In contrast, the embodiment performs a process of inserting and bonding the bump part within a third through hole while the third through hole is formed in the protective layer. Accordingly, the embodiment can allow a width of the bump part to be smaller than a width of the third through hole provided in the protective layer. For example, a side surface of the bump part may be spaced apart from an inner wall of the third through hole of the protective layer without contacting the inner wall of the third through hole of the protective layer.

Accordingly, the embodiment can prevent stress acting on the protective layer from being transferred to the bump part, thereby resolving physical and/or electrical reliability issues, such as the bump part being delaminated from the third pad or the bump part being cracked. In addition, the embodiment can resolve issues, such as contamination or damage to the protective layer occurring during a process of plating the bump part, thereby improving the product reliability of the semiconductor package.

In addition, the protective layer of the embodiment includes a first through hole overlapping the first pad in the vertical direction, a second through hole overlapping the second pad in the vertical direction, and a third through hole overlapping the third pad and the bump part in the vertical direction. A width of the first through hole is smaller than a width of the first pad, and a width of the second through hole is larger than a width of the second pad. At this time, the second through hole having a relatively large width may be provided between the first through hole and the third through hole. For example, the second through hole may be positioned closer to the third through hole than the first through hole. Furthermore, an inner wall of the second through hole may not directly contact the second pad.

Therefore, the embodiment can ensure that stress acting in a direction from the outer side of the protective layer toward the inner side of the protective layer is absorbed through the second through hole. For example, the embodiment can prevent stress acting on the protective layer from being transmitted to a region where the first and second pads are provided through the second through hole. At this time, each of the first and second pads is a terminal pad electrically connected to terminals of the semiconductor device. Therefore, when stress is applied to the first pad and the second pad, electrical opening between the circuit board and the semiconductor device may be occurred, which may cause electrical reliability problems of the semiconductor package. Accordingly, the embodiment can provide a second through hole in the protective layer, thereby efficiently distributing and/or absorbing stress applied to the region where the first and second pads are disposed. Accordingly, the semiconductor device may be stably mounted on the circuit board. Accordingly, the embodiment may allow the semiconductor device to operate stably, and thus operational reliability of products such as a semiconductor package and a server to which the semiconductor package is applied may be improved.

In addition, the embodiment can provide first to third through holes in the first protective layer disposed on one surface of the insulating layer, thereby controlling an opening ratio of the first protective layer. Therefore, the embodiment can prevent the semiconductor package from significantly warping in a specific direction by varying opening ratios of the first and second protective layers. For example, a semiconductor package can warp depending on differences in the wiring density of electrode parts disposed in each layer of the insulating layer, and accordingly, the embodiment can provide first to third through holes in the first protective layer to control the opening ratio, thereby mitigating warping caused by differences in wiring density.

### DESCRIPTION OF DRAWINGS

FIG. 1 is a cross-sectional view illustrating a semiconductor package according to an embodiment.

FIG. 2 is a plan view illustrating a through hole in a first protective layer disposed on the insulating layer of FIG. 1.

FIG. 3 is a cross-sectional view of region A of FIG. 1 according to a first embodiment in which some components are omitted.

FIG. 4 is a cross-sectional view of region A of FIG. 1 according to a second embodiment in which some components are omitted.

FIG. 5 is a cross-sectional view of region A of FIG. 1 according to a third embodiment with some components omitted.

FIG. 6 is a cross-sectional view of a semiconductor package including a main board coupled to FIG. 1.

FIGS. 7 to 17 are cross-sectional views showing a method of manufacturing the semiconductor package shown in FIG. 1 in order of processes.

### BEST MODEL

Hereinafter, embodiments will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

Further, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

In addition, the semiconductor device may be an integrated passive device (IPD). Additionally, the semiconductor device may be a multilayer ceramic capacitor (MLCC) or a silicon-based capacitor.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Circuit Board and Semiconductor Package

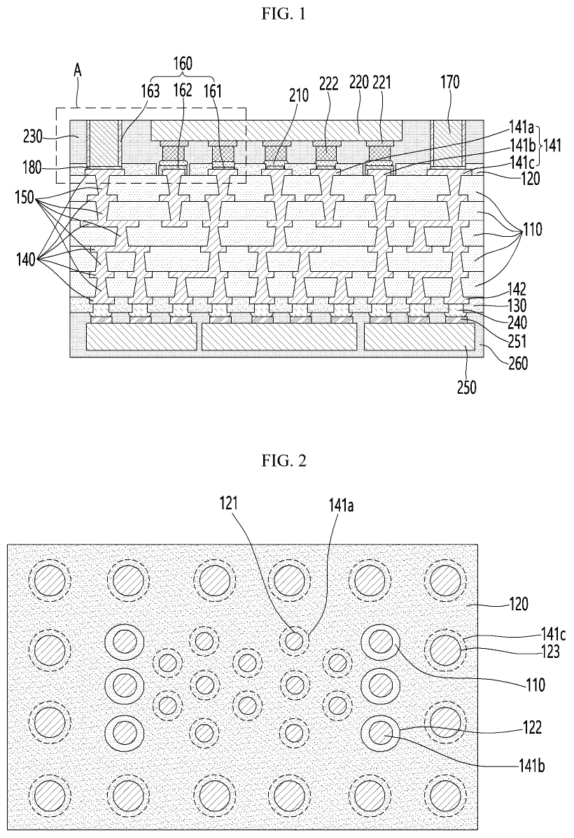

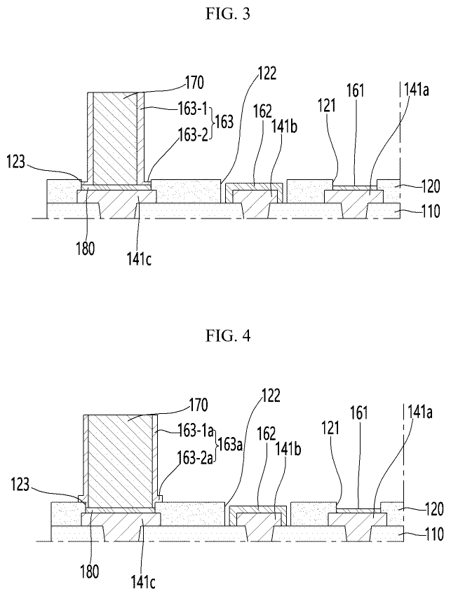

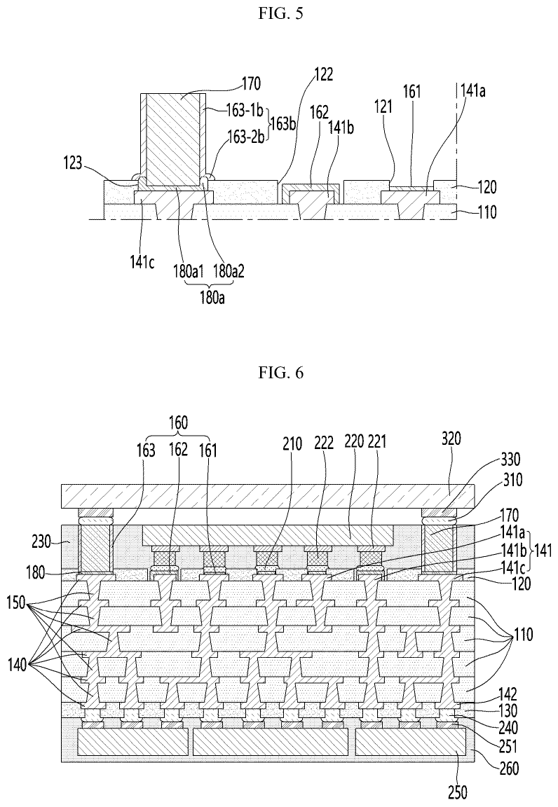

FIG. 1 is a cross-sectional view illustrating a semiconductor package according to an embodiment, FIG. 2 is a plan view illustrating a through hole in a first protective layer disposed on the insulating layer of FIG. 1, FIG. 3 is a cross-sectional view of region A of FIG. 1 according to a first embodiment in which some components are omitted, FIG. 4 is a cross-sectional view of region A of FIG. 1 according to a second embodiment in which some components are omitted, FIG. 5 is a cross-sectional view of region A of FIG. 1 according to a third embodiment with some components omitted, and FIG. 6 is a cross-sectional view of a semiconductor package including a main board coupled to FIG. 1.

Hereinafter, a circuit board and a semiconductor package including the same according to an embodiment will be described with reference to FIGS. 1 to 6.

Before describing the embodiment, the semiconductor package according to the embodiment may have a double-sided molding structure, in which semiconductor devices 220 and 250 are mounted on both sides of the circuit board, and molding members 230 and 260 are provided to mold the semiconductor devices 220 and 250 mounted on both sides of the circuit board.

Referring to FIG. 1, the semiconductor package includes a circuit board, connection parts 210 and 240, semiconductor devices 220 and 250, and molding members 230 and 260.

The circuit board includes an insulating layer 110.

The insulating layer 110 may include an organic material that has excellent processability, allows for slimming of a substrate, and does not include a reinforcing member that allows miniaturization of an electrode part (for example, a first electrode 140) provided in the circuit board. For example, the insulating layer 110 of the circuit board may use ABF (Ajinomoto Build-up Film), a product released by Ajinomoto Co., Ltd., and may use FR-4, BT (Bismaleimide Triazine), PID (Photo Image-able Dielectric resin), BT, etc., but the embodiment is not limited thereto.

The insulating layer 110 may be provided in a form in which a plurality of layers are laminated. As shown in FIG. 1, the insulating layer 110 may have a laminated structure of five layers, but is not limited thereto. For example, the insulating layer 110 may have a laminated structure of four or fewer layers, or a laminated structure of six or more layers.

In one embodiment, the plurality of layers of the insulating layer 110 may be formed of a same insulating material, but is not limited thereto. At least one of the plurality of layers of the insulating layer 110 may include an insulating material different from materials of at least the other layers.

Through the laminated structure of the insulating layer 110 described above, the circuit board of the embodiment can electrically connect the semiconductor device and the main board.

At least one of the plurality of layers of the insulating layer 110 of one embodiment may include a reinforcing member. In one embodiment, the reinforcing member may refer to glass fiber. In another embodiment, the reinforcing member may refer to GCP (Glass Core Primer). When the reinforcing member refers to glass fiber and the insulating layer including the reinforcing member has a certain thickness, the insulating layer including the reinforcing member may be provided as a core layer, and thus, the circuit board may be provided as a core board.

In addition, at least one of the plurality of layers of the insulating layer 110 can improve the rigidity of the circuit board by including a reinforcing member. For example, the reinforcing member may function to prevent the circuit board and the semiconductor package from being greatly warped in a specific direction. Therefore, the insulating layer 110 can be prevented from warping during a manufacturing process of the circuit board, thereby improving the positional accuracy of the first electrode 140 and the second electrode 150 of the electrode part, and further improving an alignment between the first electrode 140 and the second electrode 150 of the electrode part. In addition, as the rigidity of the circuit board is secured, the semiconductor device can be stably coupled to the circuit board, thereby enabling the semiconductor device to operate stably. Furthermore, electronic products such as servers to which the semiconductor package of the embodiment is applied can operate stably, thereby improving product reliability.

In addition, the circuit board includes a protective layer. For example, the circuit board includes a first protective layer 120 provided on the insulating layer 110. In addition, the circuit board includes a second protective layer 130 disposed under the insulating layer 110.

At this time, the semiconductor package of FIG. 1 may be provided in an upside-down state, and in this case, the first protective layer 120 may mean a protective layer disposed under the insulating layer 110, and the second protective layer 130 may mean a protective layer disposed on the insulating layer 110.

Since the first protective layer 120 and the second protective layer 130 do not have good wettability with solder, the first protective layer 120 and the second protective layer 130 can protect the circuit board from electrical short-circuit problems caused by contact between solders disposed on the electrode parts of the circuit board, and can protect the insulating layer 110 from external contaminants such as moisture or particles that may be exposed during the manufacturing process of the circuit board.

The first protective layer 120 may have a through hole. The through hole of the first protective layer 120 may penetrate upper and lower surfaces of the first protective layer 120. The through hole of the first protective layer 120 may be provided while overlapping the electrode part provided on the circuit board in a vertical direction.

Referring to FIG. 2, the first protective layer 120 may have a plurality of through holes. A fact that a plurality of through holes are provided in the first protective layer 120 may mean that a plurality of through holes that are not connected to each other are spaced apart in horizontal direction in the first protective layer 120.

The first protective layer 120 may have first to third through holes 121, 122, and 123. For example, the first protective layer 120 may have first to third through holes 121, 122, and 123 that overlap with different electrode parts provided on the insulating layer 110 in the vertical direction, respectively. For example, a first electrode 140 of the circuit board may include a pad part 141 disposed on the insulating layer 110. The pad part 141 may include first to third pads 141a, 141b, and 141c.

At this time, each of the first to third through holes 121, 122, and 123 of the first protective layer 120 may be overlapped with the first to third pads 141a, 141b, and 141c of the pad part 141 in the vertical direction.

The first through hole 121 of the first protective layer 120 may be overlapped with the first pad 141a disposed on the insulating layer 110 in the vertical direction. In addition, the second through hole 122 may be overlapped with the second pad 141b disposed on the insulating layer 110 in the vertical direction. In addition, the third through hole 123 may be overlapped with the third pad 141c and the bump part 170 disposed on the insulating layer in the vertical direction.

The third pad 141c may be provided in an edge region of an upper surface of the insulating layer 110 adjacent to a side surface of the insulating layer 110. For example, a plurality of third pads 141c may be provided in a circumferential direction of the upper surface of the insulating layer 110 in the edge region of the upper surface of the insulating layer 110. Accordingly, a plurality of third through holes 123 may be provided in the first protective layer 120, and each of the plurality of third through holes 123 may overlap with each of the plurality of third pads 141c in the vertical direction.

The third through hole 123 of the first protective layer 120 may have a width smaller than that of the third pad 141c. The third through hole 123 of the first protective layer 120 may partially overlap with the upper surface of the third pad 141c in the vertical direction. Accordingly, a portion of the upper surface of the third pad 141c may be covered by the first protective layer 120, and a remaining portion of the upper surface of the third pad 141c may not be covered by the first protective layer 120 through the third through hole 123.

The second through hole 122 of the first protective layer 120 may overlap with the second pad 141b of the pad part 141 disposed on the insulating layer 110 in the vertical direction. The second pad 141b may be provided in an inner region of the upper surface of the insulating layer 110. For example, the second pad 141b may be provided inside an edge region where the third pad 141c is disposed. A plurality of second pads 141b may be provided on the upper surface of the insulating layer 110. Accordingly, a plurality of third through holes 123 of the first protective layer 120 may be provided, and each of the plurality of third through holes 123 may overlap each of the plurality of third pads 141c in the vertical direction.

The second through hole 122 of the first protective layer 120 may have a width greater than the width of the second pad 141b. For example, the second through hole 122 of the first protective layer 120 may entirely overlap the upper surface of the second pad 141b in the vertical direction. Therefore, the upper surface of the second pad 141b may not contact the first protective layer 120. In addition, an inner wall of the second through hole 122 of the first protective layer 120 may be spaced apart from a side surface of the second pad 141b. For example, the inner wall of the second through hole 122 of the first protective layer 120 may be spaced apart from the side surface of the second pad 141b with a specific horizontal distance along the circumferential direction of the side surface of the second pad 141b. Therefore, each of the upper surface and the side surface of the second pad 141b may not contact the first protective layer 120.

The first through hole 121 of the first protective layer 120 may overlap with the first pad 141a of the pad part 141 disposed on the insulating layer 110 in the vertical direction. The first pad 141a may be provided in an inner region of the insulating layer 110. For example, the first pad 141a may be provided on the inner side of the edge region where the third pad 141c is disposed. A plurality of first pads 141a may be provided on the upper surface of the insulating layer 110. Accordingly, a plurality of first through holes 121 may be provided in the first protective layer 120, and accordingly, each of the plurality of first through holes 121 may overlap each of the plurality of first pads 141a in a vertical direction.

The first through hole 121 of the first protective layer 120 may have a width smaller than a width of the first pad 141a. For example, the first through hole 121 of the first protective layer 120 may partially overlap the upper surface of the first pad 141a in the vertical direction. Accordingly, at least a portion of the upper surface of the first pad 141a may be in contact with the first protective layer 120, and a remaining portion of the upper surface of the first pad 141a may not be in contact with the first protective layer 120 through the first through hole 121.

The second protective layer 130 may be provided on a lower surface of the insulating layer 110. At this time, the first electrode 140 may include a plurality of fourth pads 142 provided on the lower surface of the insulating layer 110. At this time, the second protective layer 130 may have through holes that overlaps the plurality of fourth pads 142 in the vertical direction. At this time, each of the through holes provided in the second protective layer 130 may have a width smaller than the width of the fourth pad 142. For example, the second protective layer 130 may only have a fourth through hole corresponding to the first through hole 121 provided in the first protective layer 120.

In the embodiment, the first protective layer 120 is provided with the first through hole 121, the second through hole 122, and the third through hole 123, and the second protective layer 130 is provided with the fourth through hole, thereby preventing the circuit board and the semiconductor package from being significantly warped in a specific direction. Furthermore, the embodiment allows the first protective layer 120 to have a first through hole 121, a second through hole 122, and a third through hole 123, thereby alleviating and/or dispersing stress applied to the first pad 141a and the second pad 141b, thereby improving the electrical connection reliability between the first pad 141a and/or the second pad 141b and the semiconductor device.

For example, the circuit board may be warped into a convex or concave shape due to differences in a thickness of each layer of the insulating layer 110, physical properties of each layer of the insulating layer 110, a wiring density of the first electrode 140 provided on each layer of the insulating layer 110, etc. At this time, the first protective layer 120 of the embodiment may include a first through hole 121, a second through hole 122, and a third through hole 123, and the second protective layer 130 may include a fourth through hole. Accordingly, a planar area of the first protective layer 120 disposed on the insulating layer 110 may be different from a planar area of the second protective layer 130. For example, an opening ratio of the through hole provided in the first protective layer 120 may be different from an opening ratio of the through hole provided in the second protective layer 130.

Through this, the embodiment allows the stress applied by the first protective layer 120 to be different from the stress applied by the second protective layer 130, and prevents the circuit board from being warped in a specific direction by using a difference in stress.

In addition, the first protective layer 120 of the embodiment may be provided with a second through hole 122 adjacent to the third through hole 123. For example, the second through hole 122 of the first protective layer 120 may be provided between the first through hole 121 and the third through hole 123. At this time, a width of the second through hole 122 is greater than a width of the second pad 141b, and thus, the first protective layer 120 may not come into contact with the second pad 141b.

Therefore, the embodiment may allow stress acting in a direction from the outside to the inside of the first protective layer 120 to be absorbed through the second through hole 122. For example, the embodiment can prevent the stress acting on the first protective layer 120 from being transmitted to a region where the first pad 141a and the second pad 141b are provided through the second through hole 122. At this time, the first pad 141a and the second pad 141b are terminal pads that are electrically connected to terminals of the semiconductor device. Therefore, if stress is applied to the first pad 141a and the second pad 141b, an electrical open may occur between the circuit board and the semiconductor device, which may cause an electrical reliability problem of the semiconductor package. Therefore, the embodiment can provide the second through hole 122 in the first protective layer 120, and through this, the stress acting on the region where the first pad 141a and/or the second pad 141b is provided can be efficiently distributed and/or absorbed, thereby allowing the semiconductor device to be stably mounted on the circuit board. Therefore, the embodiment can allow the semiconductor device to operate stably, thereby improving the operational reliability of products such as semiconductor packages and servers to which semiconductor packages are applied.

The circuit board includes an electrode part. Here, the electrode part may mean a configuration including a metallic material. For example, the electrode part may refer to a metal pattern that transmits an electrical signal. However, the embodiment is not limited thereto, and the electrode part may also include a metal pattern that does not transmit an electrical signal. For example, the electrode part may include a heat dissipation pattern and/or a ground pattern.

The electrode part may include a first electrode 140, a second electrode 150, and a bump part 170.

The first electrode 140 may be horizontally disposed between a plurality of layers of the insulating layer 110 and may be referred to as a wiring electrode, a conductor pattern, a metal pattern, a circuit pattern, a wiring part, a circuit part, etc. The second electrode 150 can pass through each of the plurality of layers of the insulating layer 110 in the vertical direction and may be referred to as a via electrode, a through electrode, a via part, a through part, etc.

The first electrode 140 may include pads and/or traces. The pads of the first electrode 140 may refer to wiring patterns that overlap the second electrode 150 in the vertical direction and are thus directly connected to the second electrode 150. The traces of the first electrode 140 may refer to wiring patterns of thin and long signal lines that are connected to the pads of the first electrode 140 and thus transmit signals between a plurality of pads.

The first electrode 140 includes a wiring layer disposed on an outermost layer of the insulating layer 110. The wiring layer may refer to wiring electrodes provided on uppermost and lowermost layers among the first electrodes 140 provided on each layer of the insulating layer 110.

The first electrode 140 may include pad parts 141 and 142. Pad parts 141 and 142 may refer to pads of the first electrode 140 disposed on the outermost layer of the circuit board. For example, one of the pad parts 141 and 142 may refer to pads disposed on the uppermost layer of the circuit board, and the other one may refer to pads disposed on the lowermost layer of the circuit board. For example, pad part 141 may be referred to as an upper pad part and may include pads connected to a semiconductor device and pads connected to a main board. In addition, pad part 142 may be referred to as a lower pad part and may include pads connected to a semiconductor device. However, the embodiment is not limited thereto, and relative positions of pad parts 141 and 142 may change depending on a direction in which the circuit board and/or semiconductor package are viewed.

The pad part 141 may include a plurality of pads. The pad part 141 may include a first pad 141a, a second pad 141b, and a third pad 141c.

The first pad 141a and the second pad 141b may be provided in an inner region of the insulating layer 110, and the third pad 141c may be provided in an edge region of the upper surface of the insulating layer 110. The edge region may refer to an outer region of the upper surface of the insulating layer 110 adjacent to the side surface of the insulating layer 110.

A plurality of third pads 141c may be provided in the edge region of the upper surface of the insulating layer 110. For example, a plurality of third pads 141c may be provided in the edge region of the upper surface of the insulating layer 110 along the circumferential direction of the upper surface of the insulating layer 110.

The first pad 141a and the second pad 141b may be provided in the inner region of the upper surface of the insulating layer 110. For example, the first pad 141a and the second pad 141b may be provided inside the edge region of the upper surface of the insulating layer 110 surrounded by the third pad 141c.

For example, the third pad 141c may be a pad connected to the main board and may have a width greater than each of widths of the first pad 141a and the second pad 141b.

In this case, the embodiment may provide the third pad 141c with a relatively large width along the circumferential direction of the edge region of the upper surface of the insulating layer 110. Accordingly, the embodiment may increase the rigidity of the edge region of the circuit board and prevent the circuit board from being significantly warped in a specific direction. Preferably, a bump part 170, which will be described later, may be disposed on the third pad 141c. The bump part 170 may have a thickness greater than a certain level and may be disposed on the third pad 141c.

Therefore, the embodiment can prevent the circuit board from warping into a convex and/or concave shape by utilizing the relatively large width of the third pad 141c and the bump part 170 disposed on the third pad 141c. Accordingly, the embodiment may allow the semiconductor device to be stably mounted on the circuit board.

The third pad 141c may overlap the third through hole 123 of the first protective layer 120 in the vertical direction. The third pad 141c may have a width greater than that of the third through hole 123. Accordingly, a portion of the upper surface of the third pad 141c may be covered with the first protective layer 120, and a remaining portion of the upper surface of the third pad 141c may not be covered with the first protective layer 120 by the third through hole 121.

The second pad 141b may overlap the second through hole 122 provided in the first protective layer 120 in the vertical direction. The second pad 141b may be provided in the inner region of the upper surface of the insulating layer 110. For example, the second pad 141b may be provided in the inner side of the edge region where the third pad 141c is disposed. A plurality of second pads 141b may be provided on the upper surface of the insulating layer 110. The second pad 141b may have a width smaller than the width of the second through hole 122 provided in the first protective layer 120. Therefore, the upper surface and side surfaces of the second pad 141b may not be covered by the first protective layer 120.

The first pad 141a may overlap the first through hole 121 provided in the first protective layer 120 in the vertical direction. The first pad 141a may be provided in the inner region of the upper surface of the insulating layer 110. A plurality of first pads 141a may be provided on the upper surface of the insulating layer 110. The first pad 141a may have a width larger than the width of the first through hole 121 provided in the first protective layer 120. Accordingly, at least a portion of the upper surface of the first pad 141a may be in contact with the first protective layer 120, and a remaining portion of the upper surface of the first pad 141a may not be in contact with the first protective layer 120.

At this time, the embodiment allows the second pad 141b having a width smaller than the width of the through hole provided in the first protective layer 120 to be included in the pad 141, and accordingly, a plane area of the first protective layer 120 can be adjusted to prevent the stress from acting. In addition, the second pad 141b does not contact the first protective layer 120, and thus, the stress applied to the first protective layer 120 can be effectively distributed and/or alleviated from being transferred to the second pad 141b and the first pad 141a adjacent to the second pad 141b. Through this, the embodiment can stably mount the semiconductor device on the first pad 141a and the second pad 141b, thereby stably operating the semiconductor device, and further improving the operational reliability of products such as semiconductor packages and servers to which the semiconductor package is applied.

Furthermore, the electrode part of the circuit board includes a bump part 170 disposed on the third pad 141c. The bump part 170 may protrude with a certain thickness on the third pad 141c. At this time, the bump part 170 may be provided along the circumferential direction of the upper surface of the insulating layer 110 in the edge region of the upper surface of the insulating layer 110. Therefore, the embodiment can ensure the rigidity of the circuit board and the semiconductor package by providing the bump part 170 along the circumferential direction of the upper surface of the insulating layer 110. For example, the bump part 170 may further have a function of preventing the semiconductor package from being significantly warped in a specific direction in addition to a post function for attaching the main board to the circuit board. In addition, the semiconductor package of the embodiment may be coupled with the main board using the bump part 170, thereby improving the heat dissipation characteristics of the semiconductor package. For example, semiconductor packages applied to products providing the Internet of Things (IOT), autonomous vehicles, and high-performance servers are increasing in number of semiconductor devices and/or in size of each semiconductor device due to a trend toward high integration, and accordingly, an area of the circuit board of the semiconductor package is also increasing. In addition, as the area of the semiconductor package increases or the number of semiconductor devices increases, heat generation becomes more severe, and thus there is a problem that heat dissipation characteristics must be improved significantly. In this case, the embodiment may allow the circuit board and the main board to be coupled using the bump part 170, and the heat dissipation characteristics of the semiconductor package may be further improved compared to a conventional solder bonding method. Furthermore, the embodiment uses the bump part 170 to be coupled between the circuit board and the main board, thereby improving the rigidity of the bump part compared to the conventional solder and reducing the width of the bump part in the horizontal direction. Therefore, the embodiment may improve the degree of integration of the semiconductor package, and further improve the physical and/or electrical reliability of the semiconductor package.

At this time, the bump part 170 may be attached or bonded onto the third pad 141c. Here, “attached” or “bonded” may have a different meaning than “formed” through a plating process.

For example, the bump part may be formed by electroplating on the third pad. In this case, the circuit board includes a plating seed layer for the bump part between the bump part and the third pad. Accordingly, when forming the bump part by electroplating on the third pad, a process for forming a plating seed layer for plating the bump part and a process for etching and removing the plating seed layer are required, which complicates the product process and may lower the product yield.

In an embodiment, the bump part 170 may be formed on a separate support substrate, and the bump part 170 formed on the support substrate may be attached or bonded onto the third pad 141c of the circuit board. Through this, the embodiment can improve the physical and/or electrical reliability of the bump part 170, thereby enhancing the product reliability of the semiconductor package.

For example, the embodiment does not form the bump part 170 by performing an electrolytic plating process on the third pad 141c, but instead attaches or bonds the bump part 170 formed on a separate support substrate onto the third pad 141c. To this end, a conductive bonding part 180 is positioned between the third pad 141c and the bump part 170.

The conductive bonding part 180 may be distinguished from the chemical copper plating layer and may provide a bonding force for stably attaching or bonding the bump part 170 on the third pad 141c.

Accordingly, the embodiment may remove the chemical copper plating layer that should be provided between the third pad 141c and the bump part 170, thereby improving the adhesion between the third pad 141c and the bump part 170.

For example, the chemical copper plating layer may have a porous structure, and thus, the adhesive force between the first protective layer 120 and the chemical copper plating layer may be lower than that between the conductive junction 180 of the embodiment and the first protective layer.

In contrast, the conductive bonding part 180 of the embodiment has superior strength and durability compared to the chemical copper plating layer, and may also exhibit relatively high adhesion with the first protective layer 120.

Therefore, the embodiment can improve the adhesion between the conductive bonding part 180 and the third pad 141c, thereby enhancing the physical reliability of the bump part 170 being peeled from the third pad 141c. Furthermore, the embodiment can minimize transmission loss of signals transmitted through the third pad 141c and the bump part 170 by improving the adhesion between the third pad 141c and the bump part 170, thereby improving communication characteristics.

In addition, the embodiment can form the bump part 170 on a separate support substrate, thereby ensuring that a plurality of bumps have a same height, thereby allowing the main board to stably attach to the bump part 170.

For example, when electroplating is performed on a third pad to form a plurality of bump parts, the plurality of bumps may have different heights due to plating deviation, so it may be necessary to proceed with a polishing process that equalizes the heights of the plurality of bumps. In this case, the polishing process may be performed while the bump part is disposed on the third pad, and accordingly, the circuit board may be damaged during the polishing process. For example, in the polishing process, an impact may be applied to the semiconductor device mounted on the circuit board, and accordingly, the semiconductor device may not operate stably.

In contrast, in the embodiment, after forming a bump part 170 on a separate support substrate, a polishing process may be performed to equalize the heights of a plurality of bumps. Therefore, the embodiment can prevent damage to the semiconductor package during the polishing process, thereby improving product yield. In addition, the embodiment may perform a first polishing process of the bump part 170 on the support substrate, and then perform a second polishing process while the bump part 170 is disposed on the third pad 141c. At this time, a polishing amount in the second polishing process is smaller than a polishing amount in the polishing process performed in the comparative example, and thus damage to the circuit board that may be caused by the polishing process can be minimized.

In addition, when forming a bump part by electroplating on the third pad, a process of plating the bump part must be performed after the protective layer is formed, and damage or contamination of the protective layer may occur during the process of plating the bump part. In addition, when forming a bump part by electroplating on the third pad, it may be difficult to form the bump part within a width smaller than a width of a through hole provided in the protective layer. For example, when forming a bump part by electroplating on the third pad, a width of the bump part in a region overlapping the first protective layer in a horizontal direction may be the same as a width of the through hole of the first protective layer. Therefore, when forming a bump part by performing electroplating on the third pad, the bump part comes into contact with the first protective layer, and the stress acting on the protective layer is directly transferred to the bump part, which may cause physical reliability and/or electrical reliability problems.

In contrast, the embodiment performs a process of inserting and bonding the bump part 170 within a third through hole 123 while the third through hole 123 is formed in the first protective layer 120. Accordingly, the embodiment can allow a width of the bump part 170 to be smaller than a width of the third through hole 123 provided in the first protective layer 120. For example, a side surface of the bump part 170 may be spaced apart from an inner wall of the third through hole 123 of the first protective layer 120 without contacting the inner wall of the third through hole 123 of the first protective layer 120.

Accordingly, the embodiment can prevent stress acting on the first protective layer 120 from being transferred to the bump part 170, thereby resolving physical and/or electrical reliability issues, such as the bump part 170 being delaminated from the third pad 141c or the bump part 170 being cracked. In addition, the embodiment can resolve issues, such as contamination or damage to the first protective layer 120 occurring during a process of plating the bump part 170, thereby improving the product reliability of the semiconductor package.

In addition, the circuit board includes a surface treatment part 160. The surface treatment part 160 may be provided on the surface of the electrode part and may protect the surface of the electrode part from oxidation, etc.

At this time, the surface treatment part 160 may include a first surface layer 161 disposed on the first pad 141a, a second surface layer 162 disposed on the second pad 141b, and a third surface layer 163 disposed on the bump part 170.

At this time, at least one of the first surface layer 161, the second surface layer 162, and the third surface layer 163 may include a material different from at least one other surface layer.

For example, the embodiment performs a surface treatment method of at least one of the first pad 141a, the second pad 141b, and the bump part 170 in a manner different from at least one other surface treatment method.

At this time, the third surface layer 163 may include an organic material. For example, the third surface layer 163 may be an OSP (Organic Solderability Preservative) layer. For example, the third surface layer 163 may be a surface treatment layer formed using the OSP method.

Here, the OSP method prevents copper oxidation by applying an organic material to the surface of the bump part 170 to prevent contact between air and a copper (Cu) surface. For example, during a process of manufacturing the circuit board after the bump part 170 is formed, a surface of the bump part 170 may be exposed, resulting in oxidation or damage from various contaminants. Therefore, the embodiment may place the third surface layer 163 on the surface of the bump part 170, thereby preventing oxidation and/or damage to the bump part 170 that may occur during the process of manufacturing the circuit board. In this case, the OSP method is also called a pre-flux treatment method, as the organic material applied to the surface has properties similar to flux.

The third surface layer 163 contacts the bump part 170. At this time, the third surface layer 163 may be provided on a side surface of the bump part 170, thereby contacting the first molding member 230. Therefore, the embodiment can protect the surface of the bump part 170 during the process of forming the bump part 170 using the third surface layer 163 during the process of manufacturing the circuit board. Furthermore, unlike the first surface layer 161 and the second surface layer 162, the third surface layer 163 may not contact a conductive adhesive such as solder. Accordingly, the embodiment allows the third surface layer 163 of the OSP method, which is relatively cheaper than the first surface layer 161 and the second surface layer 162, to be disposed on the surface of the bump part 170. Through this, the embodiment can lower the product cost of the semiconductor package. Furthermore, the embodiment allows the third surface layer 163 to be disposed on the bump part 170, thereby improving the adhesion with the first molding member 230. For example, the first molding member 230 has a relatively higher adhesion with the third surface layer 163 of an organic material than with the bump part 170, and thus the bump part 170 and the semiconductor device can be stably protected through the first molding member 230.

In contrast, the first surface layer 161 and the second surface layer 162 may include a different material from the third surface layer 163. For example, the first surface layer 161 and the second surface layer 162 may include a metal material. The first surface layer 161 and the second surface layer 162 may be an Electroless Nickel Immersion Gold (ENIG) layer or an Electroless Nickel Electroless Palladium Immersion Gold (ENEPIG) layer.

The first surface layer 161 and the second surface layer 162 may have different shapes.

For example, the second surface layer 162 may be positioned within the second through hole 122 of the first protective layer 120. At this time, the second through hole 122 does not contact the upper and lower surfaces of the second pad 141b. Therefore, the second surface layer 162 may be provided to entirely cover the upper and side surfaces of the second pad 141b.

In contrast, the first surface layer 161 is disposed within the first through hole 121 provided in the first protective layer 120. The upper surface of the first pad 141a partially overlaps the first through hole 121 in the vertical direction. Therefore, the first surface layer 161 may be disposed to cover a portion of the upper surface of the first pad 141a that overlaps the first through hole 121 in the vertical direction.

Therefore, the embodiment can improve the processability in the process of mounting the semiconductor device using the first surface layer 161 and the second surface layer 162, allowing the semiconductor device to be stably mounted on the circuit board, and thus allowing the semiconductor device to operate stably.

A conductive bonding part 180 is disposed between the third pad 141c and the bump part 170. The conductive bonding part 180 is disposed within the third through hole 123 of the first protective layer 120. For example, the conductive bonding part 180 may be disposed on the upper surface of the third pad 141c that overlaps the third through hole 123 of the first protective layer 120 in the vertical direction.

The conductive bonding part 180 may provide bonding force between the third pad 141c and the bump part 170. Furthermore, the conductive bonding part 180 may electrically couple the third pad 141c and the bump part 170.

In one embodiment, the conductive bonding part 180 may be formed through a same process as the first surface layer 161 or the second surface layer 162. For example, the conductive bonding part 180 may be formed together with the first surface layer 161 and the second surface layer 162 in a process of forming the first surface layer 161 and the second surface layer 162. For example, the conductive bonding part 180 may be an Electroless Nickel Immersion Gold (ENIG) layer or an Electroless Nickel Electroless Palladium Immersion Gold (ENEPIG) layer. When the conductive bonding part 180 includes the same metal material as the first surface layer 161 or the second surface layer 162, the conductive bonding part 180 may be provided flatly between the third pad 141c and the bump part 170.

In another embodiment, the conductive bonding part 180 may include solder. For example, the conductive bonding part 180 may be a solder layer disposed on the third pad 141c. For example, the conductive bonding part 180 may be solder paste. For example, the conductive bonding part 150 may contain a material of different components in the solder. For example, the conductive bonding part 150 may include at least one solder selected from groups consisting of Sn-Cu, Sn-Pb, and Sn-Ag-Cu. In addition, the conductive bonding part 180 may include a material of at least one heterogeneous component of Al, Sb, Bi, Cu, Ni, In, Pb, Ag, Sn, Zn, Ga, Cd, and Fe. Meanwhile, the embodiment is not limited thereto, and the conductive bonding part 180 may be composed of a solder paste including pure solder.

Referring to FIG. 3, the conductive bonding part 180 may include the same material as the first surface layer 161 or the second surface layer 162.

Therefore, the conductive bonding part 180 may be provided flatly on the third pad 141c and the bump part 170. For example, an upper surface of the conductive bonding part 180 may not be higher than the lower surface of the bump part 170.

At this time, the bump part 170 is disposed on the conductive bonding part 180. A width of the bump part 170 in the horizontal direction may be smaller than a width of the third through hole 123 of the first protective layer 120. Therefore, a side surface of the bump part 170 may be spaced apart from an inner wall of the third through hole 123 of the first protective layer 120.

The third surface layer 163 may be disposed on the surface of the bump part 170. For example, the third surface layer 163 may be disposed on the side surface of the bump part 170. However, during a process of manufacturing process the circuit board, the third surface layer 163 may also be disposed on the upper surface of the bump part 170, but may be selectively removed by a polishing process performed after forming the first molding member 230.

The third surface layer 163 may include a first portion 163-1 disposed on the side surface of the bump part 170. The first portion 163-1 of the third surface layer 163 may extend along the side surface of the bump part 170. The third surface layer 163 may include a second portion 163-2 bent from the first portion 163-1. The second portion 163-2 of the third surface layer 163 may extend from the first portion 163-1 and be disposed on the conductive bonding part 180. Accordingly, the second portion 163-2 of the third surface layer 163 may cover the upper surface of the conductive bonding part 180 that does not overlap with the bump part 170 in the vertical direction, thereby stably protecting the conductive bonding part 180. At this time, the upper surface of the second portion 163-2 of the third surface layer 163 may be positioned lower than the upper surface of the first protective layer 120. Accordingly, the second portion 163-2 of the third surface layer 163 and the upper surface of the first protective layer 120 may have a step, and the first molding member 230 may be provided on the step between the second portion 163-2 of the third surface layer 163 and the first protective layer 120. Through this, the embodiment can increase a bonding area with the first molding member 230, and accordingly, the bump part 170 and the semiconductor device can be protected more stably through the first molding member 230.

Referring to FIG. 4, the conductive bonding part 180 may include the same material as the first surface layer 161 or the second surface layer 162. Therefore, the conductive bonding part 180 may be provided flatly on the third pad 141c and the bump part 170. For example, the upper surface of the conductive bonding part 180 may not be higher than the lower surface of the bump part 170.

At this time, the bump part 170 is disposed on the conductive bonding part 180. The width of the bump part 170 in the horizontal direction may be smaller than the width of the third through hole 123 of the first protective layer 120. Therefore, the side surface of the bump part 170 may be spaced apart from the inner wall of the third through hole 123 of the first protective layer 120.

The third surface layer 163a may be disposed on the surface of the bump part 170. For example, the third surface layer 163a may be disposed on the side surface of the bump part 170. However, during a process of manufacturing the circuit board, the third surface layer 163a may also be disposed on the upper surface of the bump part 170, but may be selectively removed by a polishing process performed after forming the first molding member 230.

The third surface layer 163a may include a first portion 163-1a disposed on the side surface of the bump part 170. The first portion 163-1a of the third surface layer 163a may extend along the side surface of the bump part 170. The first portion 163-la of the third surface layer 163a may be provided along the circumferential direction of the inner wall of the third through hole 123, and may fill a gap between the third through hole 123 and the bump part 170.

The third surface layer 163a may include a second portion 163-2a bent from the first portion 163-1a. The second portion 163-2a of the third surface layer 163a may extend from the first portion 163-1a and be disposed on the first protective layer 120.

The second portion 163-2a of the third surface layer 163a may contact the first protective layer 120 and serve as an anchor to increase adhesion between the third surface layer 163a and the first protective layer 120. In addition, the second portion 163-2a of the third surface layer 163a and the upper surface of the first protective layer 120 may have a step, and the first molding member 230 may be provided on the step between the second portion 163-2a of the third surface layer 163a and the first protective layer 120. Through this, the embodiment can increase the bonding area with the first molding member 230, thereby enabling the bump part 170 and the semiconductor device to be more stably protected through the first molding member 230.

Referring to FIG. 5, the conductive bonding part 180a may include solder.

Therefore, the conductive bonding part 180a may extend upward during a process of bonding the bump part 170.

For example, the conductive bonding part 180a may include a flat portion 180al disposed between the third pad 141c and the bump part 170, and an extension portion 180a2 extending from the flat portion 180al toward the upper surface of the first protective layer 120.

The extension portion 180a2 of the conductive bonding part 180a may be provided between the inner wall of the third through hole 123 of the first protective layer 120 and the side surface of the bump part 170. The extension portion 180a2 of the conductive bonding part 180a may be provided to fill a gap between the inner wall of the third through hole 123 of the first protective layer 120 and the side surface of the bump part 170. The extension portion 180a2 may cover at least a portion of the side surface of the bump part 170. For example, the extension portion 180a2 may be provided to surround at least a portion of the side surface of the bump part 170 that overlaps the inner wall of the third through hole 123 of the first protective layer 120 in the horizontal direction. Through this, the embodiment can further improve the bonding strength between the third pad 141c and the bump part 170 by using the extension portion 180a2 of the conductive bonding part 180a, thereby solving the reliability problem of the bump part 170 being peeled off from the third pad 141c.

At this time, an upper surface of the extension portion 180a2 of the conductive bonding part 180a may include a convex surface. For example, the upper surface of the extension portion 180a2 of the conductive bonding part 180a may have a convex shape toward the upper surface of the bump part 170.

The third surface layer 163b may be disposed on the surface of the bump part 170. For example, the third surface layer 163b may be disposed on the side surface of the bump part 170. The third surface layer 163b may include a first portion 163-1b disposed on the side surface of the bump part 170. The first portion 163-1b of the third surface layer 163a may extend along the side surface of the bump part 170.

The third surface layer 163b may include a second portion 163-2b bent from the first portion 163-1b. The second portion 163-2b of the third surface layer 163b may extend outward from the first portion 163-1b. The second portion 163-2b of the third surface layer 163b may be provided to cover the convex surface of the extension portion 180a2 of the conductive bonding part 180a. In addition, the second portion 163-2b of the third surface layer 163b may cover at least a portion of the upper surface of the first protective layer 120. Accordingly, the second portion 163-2b of the third surface layer 163b may overlap the extension portion 180a2 of the conductive bonding part 180a in the horizontal direction. Through this, the embodiment may further increase the contact area between the third surface layer 163b and the conductive bonding part 180a.

Referring again to FIG. 1, the semiconductor package of the embodiment includes connection parts 210 and 240. For example, the semiconductor package may include a first connection part 210 disposed on a first pad 141a and a second pad 141b. Furthermore, the semiconductor package may include a second connection part 240 disposed under fourth pads 142 provided at a lowermost side of the circuit board.

The first and second connection parts 210 and 240 may be bonded using at least one of wire bonding, solder bonding, and direct metal-to-metal bonding.

The wire bonding method electrically connects an electrode part of a circuit board to a terminal of a semiconductor device using a conductor such as gold (Au).

The solder bonding method electrically connects an electrode part of a circuit board to a terminal of a semiconductor device using a material including at least one of Sn, Ag, and Cu.

Direct metal-to-metal bonding refers to a process of applying heat and pressure between an electrode part and a terminal of a semiconductor device to recrystallize the electrode part without the use of solder, wire, or conductive adhesive, thereby directly bonding the electrode part and the terminal of the semiconductor device. In this case, the first and second connection parts 210 and 240 may refer to metal layers formed between the electrode part and the terminal of the semiconductor device by recrystallization.

For example, the first and second connection parts 210 and 240 can electrically connect the electrode part and the terminal of the semiconductor device using thermal compression bonding. Thermal compression bonding can reduce the volume of the first and second connection parts 210 and 240 and prevent short circuits between adjacent connection parts. Therefore, thermal compression bonding may be advantageous when the terminal and/or electrode part of the semiconductor device have a fine pitch.

In addition, the semiconductor package may include semiconductor devices disposed on the first and second connection parts 210 and 240.

For example, the semiconductor package includes a first semiconductor device 220 coupled to the first connection part 210. The first semiconductor device 220 may include a terminal 221. The terminal 221 of the first semiconductor device 220 may be electrically connected to the first pad 141a and the second pad 141b of the circuit board via the first connection part 210. According to an embodiment, the first semiconductor device 220 may include a conductive pillar 222 disposed on the terminal 221, but is not limited thereto. The conductive pillar 222 may be provided to separate the terminal 221 of the first semiconductor device 220 and the first pad 141a/the second pad 141b at a predetermined spacing along the vertical direction, thereby improving the alignment between the terminal 221 of the first semiconductor device 220 and the first pad 141a and second pad 141b.

The embodiment may include a first molding member 230. The first molding member 230 may mold the bump part 170 and the first semiconductor device 220 on the insulating layer 110.

An upper surface of the first molding member 230 may not be higher than the upper surface of the first semiconductor device 220. For example, the upper surface of the first molding member 230 may be positioned on the same plane as the upper surface of the first semiconductor device 220. For example, the upper surface of the first semiconductor device 220 may not be covered by the first molding member 230. Through this, the embodiment can allow the first semiconductor device 220 to be exposed to the outside of the circuit board, thereby allowing heat generated from the first semiconductor device 220 to be easily dissipated. Therefore, the embodiment can improve the heat dissipation characteristics of the semiconductor package, thereby enabling the first semiconductor device 220 to operate more stably.

The semiconductor package may include a second semiconductor device 250 disposed under a second connection part 240. The second semiconductor device 250 may be provided in multiple units spaced apart in the horizontal direction on the circuit board. The terminal 251 of the second semiconductor device 250 may be electrically connected to the fourth pads 142 of the circuit board via the second connection part 240.

The semiconductor package may include a second molding member 260. The second molding member 260 can mold the second semiconductor device 250.

In addition, referring to FIG. 6, the semiconductor package may further include a third connection part 310 disposed on the bump part 170. At this time, at least a portion of the upper surface of the bump part 170 may not be covered by the first molding member 230, and thus the third connection part 310 may be disposed on the bump part 170.

The third connection part 310 may be provided on the bump part 170. The third connection part 310 may be solder, but is not limited thereto. Furthermore, the semiconductor package may include a main board 320 coupled to the bump part 170 via the third connection part 310.

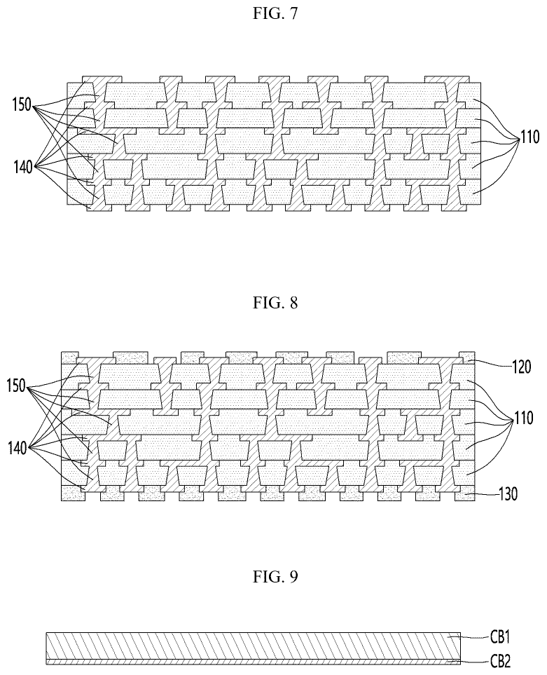

FIGS. 7 to 17 are cross-sectional views showing a method of manufacturing the semiconductor package shown in FIG. 1 in order of processes.

Referring to FIG. 7, the embodiment may perform a process for manufacturing a substrate. For example, the embodiment may perform a process of preparing a carrier board, a process of forming a first layer of an insulating layer 110 on the carrier board, and a process of forming a first electrode 140 and a second electrode 150 on the first layer of the insulating layer 110. Thereafter, the embodiment may perform a process of removing the carrier board. Thereafter, the embodiment may repeat a process of laminating an additional insulating layer on upper and lower portions of the first layer of the insulating layer 110, and a process of forming a first electrode 140 and a second electrode 150 on the additional insulating layer.

Referring to FIG. 8, the embodiment may perform a process of forming a protective layer. For example, the embodiment may perform a process of forming a first protective layer 120 on an uppermost layer among the plurality of insulating layers 110. In addition, the embodiment may perform a process of laminating a second protective layer 130 under a lowermost layer among the plurality of insulating layers 110. Thereafter, the embodiment may perform a process of forming a through hole in each of the first protective layer 120 and the second protective layer 130. For example, the embodiment may perform a process of forming a first through hole 121, a second through hole 122, and a third through hole 123 that overlap the first pad 141a, the second pad 141b, and the third pad 141c of the pad part 141 in the first protective layer 120 in the vertical direction, respectively. In addition, the embodiment may perform a process of forming a fourth through hole in the second protective layer 130 that overlaps the fourth pad 142 in the vertical direction.

Next, the embodiment may perform a process of manufacturing a bump part 170. At this time, the bump part 170 may be manufactured on a separate support substrate rather than the circuit board manufactured in FIG. 8.

Referring to FIG. 9, the embodiment may perform a process of preparing a support substrate. The support substrate may include a support insulating layer CB1 and a support metal layer CB2.

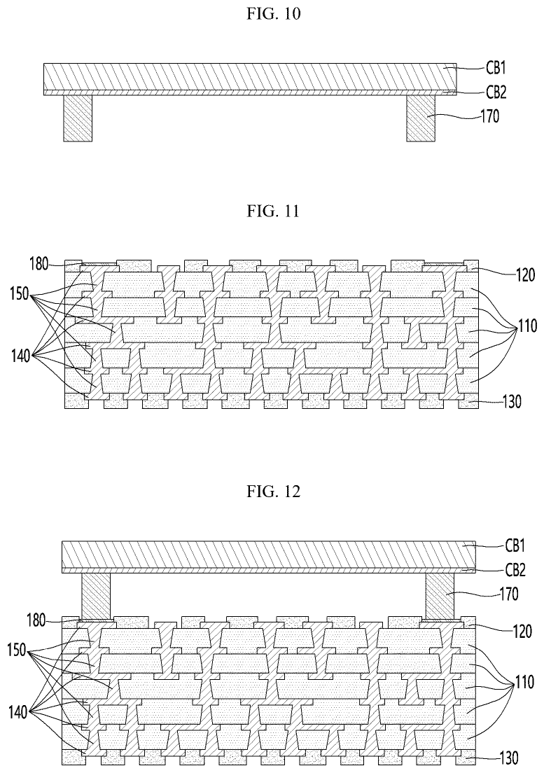

Referring to FIG. 10, the embodiment may perform a process of forming a bump part 170 under the support metal layer CB2. For example, the embodiment may perform a process of laminating a dry film having an opening under the support metal layer CB2 and a process of forming the bump part 170 by filling the opening of the dry film with a conductive material using the support metal layer CB2 as a seed layer.

Referring to FIG. 11, the embodiment may perform a process of forming a conductive bonding part 180 on the third pad 141c of the circuit board manufactured through FIG. 8. In one embodiment, the conductive bonding part 180 may be an Electroless Nickel Immersion Gold (ENIG) layer or an Electroless Nickel Electroless Palladium Immersion Gold (ENEPIG) layer. In another embodiment, the conductive bonding part 180 may be solder.

Referring to FIG. 12, the embodiment may perform a process of bonding a circuit board and a support substrate. For example, the embodiment may perform a process of aligning a bump part 170 provided on the support substrate and a conductive bonding part 180 disposed on the third pad 141c in the vertical direction, and bonding the bump part 170 on the third pad 141c using the conductive bonding part 180.

Referring to FIG. 13, the embodiment may perform a process of removing the support insulating layer and the support metal layer of the support substrate provided on the bump part 170. Through this, the bump part 170 may have a structure bonded to the conductive bonding part 180.

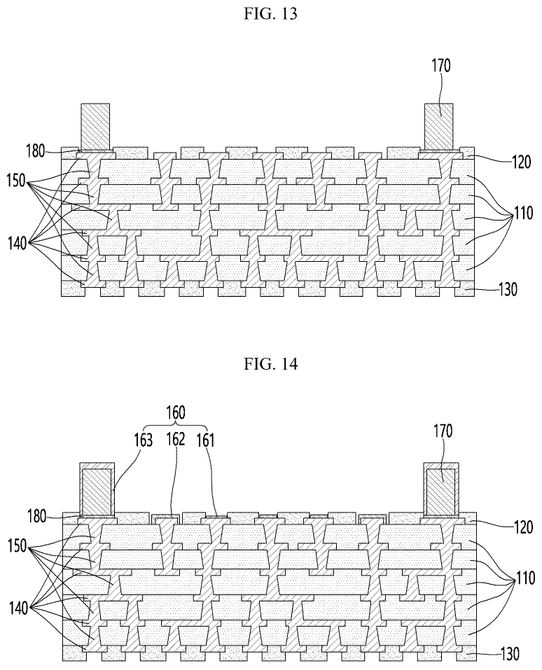

Referring to FIG. 14, the embodiment may perform a process of forming a surface treatment part 160. For example, the embodiment may perform a process of forming a third surface layer 163 on upper and side surfaces of the bump part 170. In addition, the embodiment may perform a process of forming a first surface layer 161 and a second surface layer 162 on the surfaces of the first pad 141a and the second pad 141b.

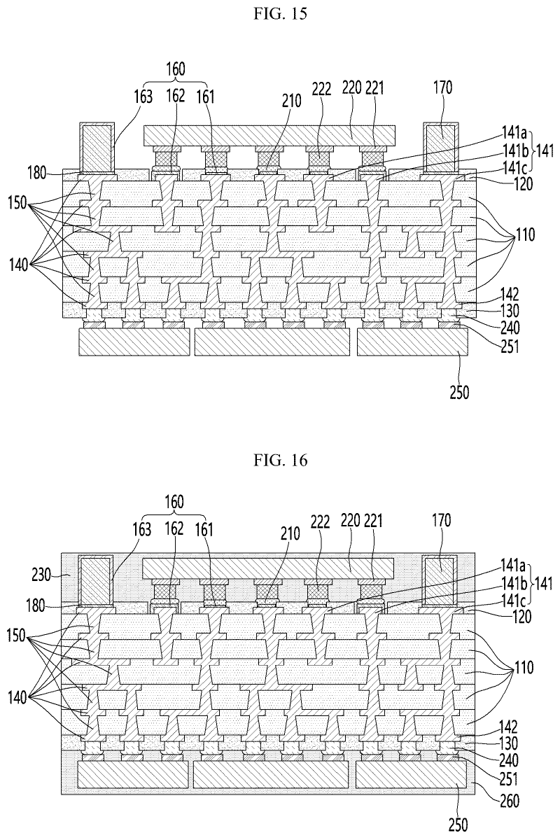

Referring to FIG. 15, the embodiment may perform a process of placing a first connection part 210 on the first surface layer 161 and the second surface layer 162. In addition, the embodiment may perform a process of placing a second connection part 240 under the fourth pad 142. In addition, the embodiment may perform a process of mounting a first semiconductor device 220 on the first connection part 210 and a process of mounting a second semiconductor device 250 under the second connection part 240.

Referring to FIG. 16, the embodiment may perform a process of forming a first molding member 230 for molding the first semiconductor device 220 and the bump part 170 and a second molding member 260 for molding the second semiconductor device 250.

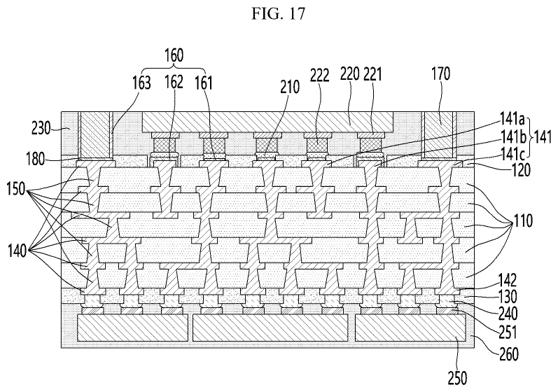

Referring to FIG. 17, the embodiment may perform a process of polishing an upper region of the first molding member 230. At this time, the polishing of the upper region of the first molding member 230 may be performed so that the upper surface of the first semiconductor device 220 is exposed, but is not limited thereto. In addition, a part of the third surface layer 163 may be removed in the polishing process of the first molding member 230. For example, when a part of the third surface layer 163 is removed in the polishing process of the first molding member 230, the third surface layer 163 provided on the upper surface of the bump part 170 may be removed, and accordingly, the third surface layer 163 may be provided only on the side surface of the bump part 170.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a build-up insulating layer including a plurality of insulating layers stacked in a vertical direction;
an electrode part disposed on the build-up insulating layer; and
a surface treatment part disposed on the electrode part,
wherein the electrode part includes:
a first pad disposed on the build-up insulating layer; and
a second pad disposed on the build-up insulating layer and spaced apart from the first pad in a horizontal direction,
wherein the surface treatment part includes:
a first surface layer provided to cover a portion of an upper surface of the first pad; and
a second surface layer provided to surround upper and side surfaces of the second pad.

2. The circuit board of claim 1, wherein the electrode part includes: a third pad disposed on the build-up insulating layer and spaced apart from the first and second pads in the horizontal direction; and
a bump part disposed on the third pad,
wherein the surface treatment part includes a third surface layer provided to surround a side surface of the bump part.

3. The circuit board of claim 2, wherein the first and second surface layers include a same material.

4. The circuit board of claim 2, wherein the third surface layer includes a material different from materials of the first and second surface layers.

5. The circuit board of claim 2, wherein the first and second surface layers are an Electroless Nickel Immersion Gold (ENIG) layer or an Electroless Nickel Electroless Palladium Immersion Gold (ENEPIG) layer, and
wherein the third surface layer is an Organic Solderability Preservative (OSP) layer.

6. The circuit board of claim 2, wherein the third surface layer does not contact the third pad.

7. The circuit board of claim 4, wherein the third pad is a plurality of third pads that are provided along a circumferential direction of an upper surface of the build-up insulating layer and are provided in an outer region of the upper surface of the build-up insulating layer adjacent to a side surface of the build-up insulating layer, and
wherein the first pad and the second pad are provided in an inner region of the upper surface of the build-up insulating layer excluding the outer region.

8. The circuit board of claim 2, comprising:
a protective layer disposed on the build-up insulating layer,
wherein the protective layer includes a first through hole overlapping the first pad in a vertical direction, a second through hole overlapping the second pad in the vertical direction, and a third through hole overlapping the third pad in the vertical direction, and
wherein a width of at least one of the first to third through holes in the horizontal direction is different from a width of at least one other through hole in the horizontal direction.

9. The circuit board of claim 7, wherein a width of the first through hole in the horizontal direction is smaller than a width of the first pad in the horizontal direction, and
wherein a width of the second through hole in the horizontal direction is greater than a width of the second pad in the horizontal direction.

10. The circuit board of claim 9, wherein a width of the third through hole in the horizontal direction is smaller than a width of the third pad in the horizontal direction.

11. The circuit board of claim 9, wherein a width of the bump part in the horizontal direction is smaller than a width of the third through hole in the horizontal direction, and
wherein an inner wall of the third through hole does not contact the bump part.

12. The circuit board of claim 9, comprising:
a conductive bonding part disposed between the third pad and the bump part.

13. The circuit board of claim 12, wherein the conductive bonding part includes a same material as the first and second surface layers.

14. The circuit board of claim 13, wherein the conductive bonding part is disposed flatly on the third pad, and
wherein the bump part does not overlap the conductive bonding part in the horizontal direction.

15. The circuit board of claim 12, wherein the conductive bonding part includes solder, and
wherein the conductive bonding part includes a flat portion disposed between the third pad and the bump part; and an extension portion extending from the flat portion and disposed between an inner wall of the third through hole and a side surface of the bump part.

16. The circuit board of claim 15, wherein an upper surface of the extension portion includes a convex surface, and
wherein at least a portion of the third surface layer is disposed to overlap the extension portion in the horizontal direction and cover the convex surface of the extension portion.

17. The circuit board of claim 3, comprising:
a semiconductor device disposed on the first pad and the second pad.

18. The circuit board of claim 17, comprising:
a molding member molding the semiconductor device and the bump part, and
wherein the molding member contacts the third surface layer and does not contact the bump part.

19. A circuit board comprising:
a build-up insulating layer including a plurality of insulating layers stacked in a vertical direction;
an electrode part disposed on the build-up insulating layer; and
a surface treatment part disposed on the electrode part,
wherein the electrode part includes first to third pads disposed on the insulating layer and spaced apart from each other in a horizontal direction; and a bump part disposed on the third pad,
wherein the surface treatment part includes a first surface layer provided to cover a portion of an upper surface of the first pad; a second surface layer provided to surround an upper surface and a side surface of the second pad; and a third surface layer provided to surround the side surface of the bump part,
wherein a plurality of third pads are provided along a circumferential direction of the upper surface of the build-up insulating layer in an outer region of the upper surface of the build-up insulating layer adjacent to a side surface of the build-up insulating layer, and
wherein the first pad and the second pad are provided in an inner region of the upper surface of the insulating layer excluding the outer region.

20. The circuit board of claim 19, wherein the first and second surface layers includes a same material, and
wherein the third surface layer includes a material different from materials of the first and second surface layers.
